(19) United States
(12) Patent Application Publication
(10) Pub. No.: US 2024/0118131 A1
(43) Pub. Date: Apr. 11, 2024

(54) INTEGRATED DEVICE PACKAGE

(71) Applicant: ANALOG DEVICES INTERNATIONAL UNLIMITED COMPANY, Limerick (IE)

(72) Inventors: Johnny Solana Gealon, Davao del Sur (PH); Gharry Maala Bathan, Taguig City (PH); Jettro Alcantara Satsatin, Sta. Rosa (PH); Chai Wong Lee, Taipei City, Taiwan (TW); Johann Philip Trinidad Ignacio, Dasmarinas City (PH)

(21) Appl. No.: 18/546,261

(22) PCT Filed: Feb. 11, 2022
(86) PCT No.: PCT/EP2022/053374

§ 371 Date: Aug. 11, 2023

Related U.S. Application Data
(60) Provisional application No. 63/149,128, filed on Feb. 12, 2021.

(51) Int. Cl. G01H 11/08; B81B 7/00

(52) U.S. Cl. CPC G01H 11/08; B81B 7/0032; B81B 2201/0285

(57) ABSTRACT

A sensor package is disclosed. The sensor package can include a support structure that is configured to couple with a vibration source by way of a stud. The sensor package can include a cap that is at least partially disposed over the support structure. The cap at least partially defines a cavity. The sensor package can include a vibration sensor module that is coupled to a portion of the support structure and disposed in the cavity. The sensor package can have a mechanical resonant frequency in a range of 0.1 Hz to 11 kHz. The sensor package can include a connector that is coupled to the support structure. The connector can connect to a connection line is electrically connect the vibration sensor module to an external substrate or system. The support structure can include a material that has a Young's modulus of at least 60 GPa and a density less than 3000 kg/m3. The sensor package can include a filler material disposed in the cavity.

### CROSS-REFERENCE TO RELATED APPLICATIONS

This application claims priority to U.S. Provisional Patent Application No. 63/149,128, filed Feb. 12, 2021, the entire contents of which are incorporated by reference herein for all purposes.

### BACKGROUND

### Field

The disclosure relates to integrated device packages and, in particular, to sensor packages.

### Description of the Related Art

A sensor, such as an integrated electronics piezoelectric (IEPE) sensor, is used for sensing movement of a movement source. The sensor can be packaged to define a sensor device. When a resonant frequency of the sensor device overlaps with operational frequencies of the movement source, the accuracy of the sensor device can be degraded. Accordingly, there remains a continuing need for improved packages for sensor devices.

### BRIEF DESCRIPTION OF THE DRAWINGS

FIG. 1A is a schematic perspective view of a sensor device according to one embodiment.

FIG. 1B is a schematic side view of the sensor device of FIG. 1A.

FIG. 1C is a schematic exploded view of the sensor device of FIGS. 1A and 1B.

FIG. 1D is a schematic top plan view of a sensor device according to an embodiment.

FIG. 1E is a schematic side view of the sensor device of FIG. 1D.

FIG. 1F is another schematic side view of the sensor device of FIGS. 1D and 1E.

FIG. 2A is a schematic perspective view of a sensor device according to one embodiment.

FIG. 2B is a schematic top plan view of the sensor device of FIG. 2A.

FIG. 2C is a schematic side view of the sensor device of FIGS. 2A and 2B.

FIG. 2D is a schematic bottom plan view of the sensor device of FIGS. 2A-2C.

FIG. 2E is a schematic cross-sectional side view of the sensor device of FIGS. 2A-2D.

FIG. 2F is an exploded view of the sensor device of FIGS. 2A-2E.

FIG. 3A is a schematic top plan view of the support structure the sensor device of FIGS. 2A-2F.

FIG. 3B is a schematic front side view of the support structure.

FIG. 3C is a schematic cross-sectional side view of the support structure.

FIG. 4A is a schematic side view of the cap of the sensor device of FIGS. 2A-2F.

FIG. 4B is a schematic cross-sectional side view of the cap.

FIG. 5 shows a schematic diagram of a sensor device.

FIG. 6 is a schematic cross sectional side view of a sensor device according to an embodiment.

FIG. 7 is a graph showing resonant frequency response curves of two different sensor devices.

FIG. 8 is a schematic perspective view of a support structure according to an embodiment.

FIG. 9 is an exploded view of a sensor device according to another embodiment.

FIG. 10A is a schematic top plan view of the sensor device of FIG. 9.

FIG. 10B is a schematic side view of the sensor device of FIG. 9.

FIG. 10C is a schematic cross-sectional side view of the sensor device of FIG. 9.

FIG. 11A is a schematic perspective view of a support structure of the sensor device of FIG. 9.

FIG. 11B is a schematic top plan view of the support structure of FIG. 11A.

FIG. 11C is a schematic side view of the support structure of FIG. 11A.

FIG. 11D is a schematic cross-sectional side view of the support structure of FIG. 11A.

FIG. 12A is a schematic perspective view of a cap of the sensor device of FIG. 9.

FIG. 12B is a schematic side view of the cap of FIG. 12A.

FIG. 12C is a schematic cross-sectional side view of the cap of FIG. 12A.

FIG. 12D is a schematic top plan view of the cap of FIG. 12A.

### DETAILED DESCRIPTION

A sensor can comprise a vibration sensor that can be used to monitor vibration of a vibration source such as a steam pipe or boiler wall in a power plant, a tailpipe or engine of an automobile, etc. The sensor can also detect tilt, shock and/or vibration of, for example, a motor or engine. Piezoelectric sensors have been used to measure vibration data, such as relatively high frequency (10 kHz and more) vibrations and/or ultralow noise (25 μg/√Hz or lower) vibration data. An integrated electronics piezoelectric (IEPE) interface is an established sensor interface for piezoelectric sensors. It can be beneficial to have an IEPE interface for a sensor module that includes sensors other than a piezoelectric sensor to easily replace the conventional piezoelectric sensors. For example, the IEPE interface utilizes a connector, such as a subminiature version A (SMA) connector, for connecting the sensor device to an external substrate or system. Various embodiments disclosed herein relate to IEPE interface sensors that includes sensors other than a piezoelectric sensor, such as a microelectromechanical systems (MEMs) sensor.

A mechanical resonant frequency of a sensor device can affect the accuracy with which vibrations are detected. For example, if the resonant frequency of the sensor device overlaps with operational frequencies of the sensor, e.g., vibration frequencies of a vibration source, such as a motor, etc., then the vibration source can induce high amplitude vibrations in the sensor device itself, which can reduce the accuracy of the sensor device. Therefore, the sensor device can be designed based at least in part on a target frequency, or range of target frequencies, of the vibration source. In some applications, it can be beneficial to design the sensor device such that the mechanical resonant frequency of the sensor device is different from, e.g., above, the frequency(ies) of vibration of the vibration source so as to reduce errors and/or maintain measurement accuracy.

Various embodiments disclosed herein relate to sensor devices. In some embodiments, a sensor device can comprise a vibration sensor device. The sensor device can comprise a housing that includes a support structure and a cap. The support structure can include a base or platform and a carrier. The base and the cap can at least partially define a cavity in which the carrier is disposed. The sensor device can comprise a sensor module that includes a sensor die mounted on a substrate. In some embodiments, the sensor module can comprise EVAL-CN0532-EBZ manufactured by Analog Devices, Inc. In some embodiments, the sensor die can comprise ADXL1002 manufactured by Analog Devices, Inc. The sensor module can be coupled to the carrier of the support structure and disposed in the cavity. An elasticity and a weight of the housing of a vibration sensor device can contribute to a mechanical resonant frequency of the sensor device. At least a portion of the housing can comprise a material that has a relatively high Young's modulus and a relatively light weight or low density. Such high Young's modulus and light weight or low density materials can provide a relatively high mechanical resonant frequency. In some embodiments, the material of the housing can comprise aluminum. In other embodiments, the material of the housing can comprise stainless steel or other suitable material (e.g., other suitable metal). In some embodiments, the material of the housing can be selected to enable the sensor device to have the mechanical resonant frequency above a resonant frequency of the sensor die. For example, the mechanical resonant frequency can be above 5 kHz, above 7 kHz, or above 10 kHz. For example, the mechanical resonant frequency can be in a range of 5 kHz to 50 kHz, in a range of 7 kHz to 50 kHz, in a range of 5 kHz to 20 kHz, in a range of 7 kHz to 20 kHz, in a range of 10 kHz to 20 kHz, in a range of 5 kHz to 15 kHz, or in a range of 7 kHz to 15 kHz. In some embodiments, an epoxy can be filled in the cavity. In some embodiments, the epoxy can contribute to increasing the resonant frequency.

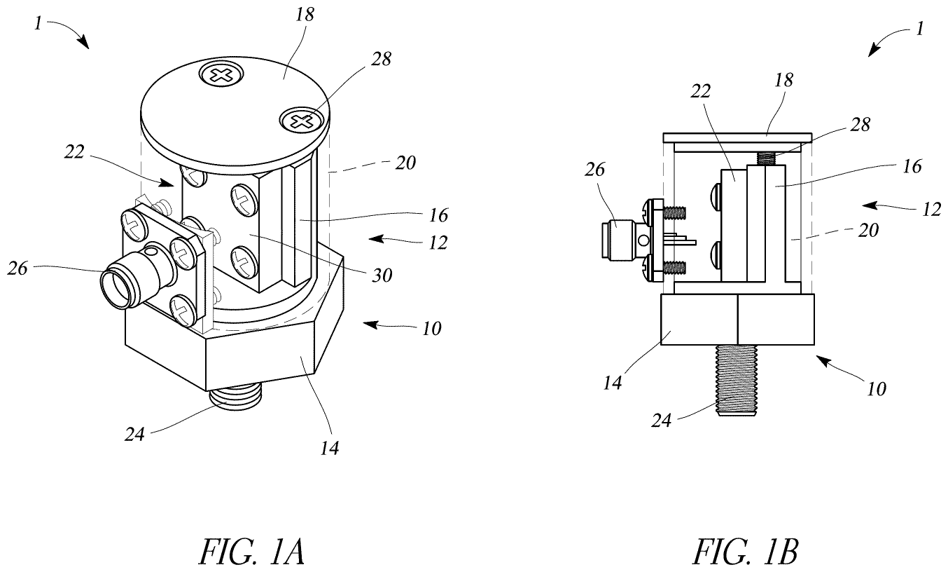

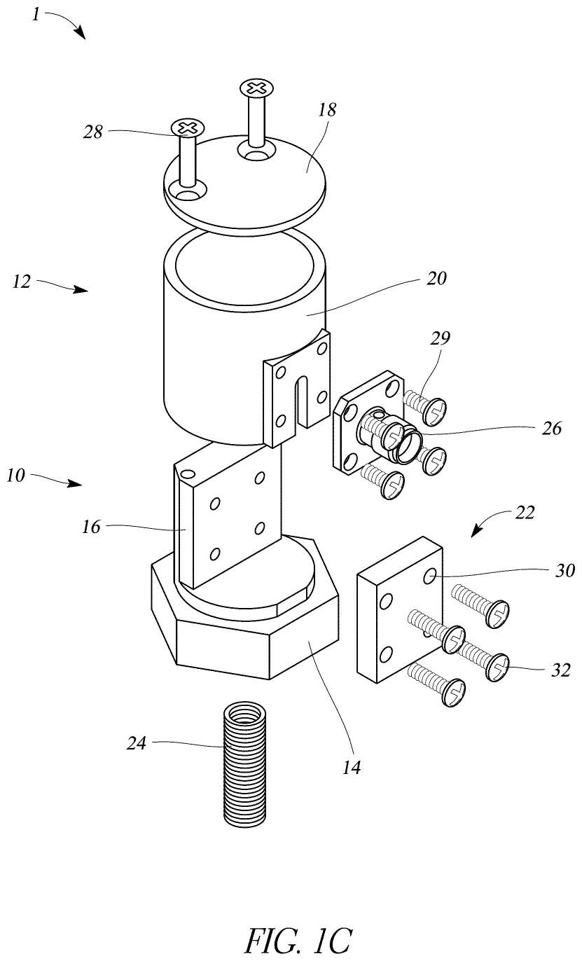

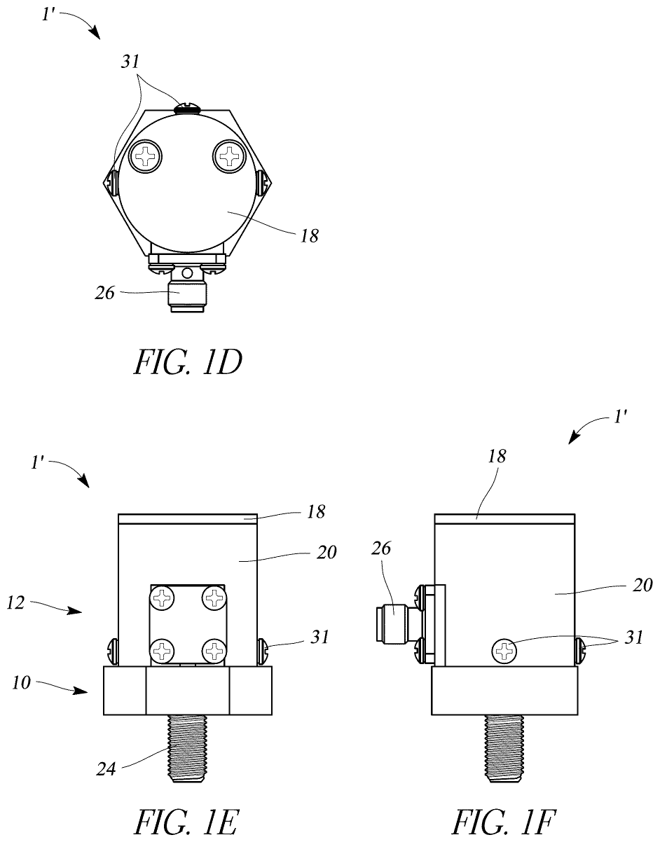

FIG. 1A is a schematic perspective view of a sensor device 1 according to one embodiment. FIG. 1B is a schematic side view of the sensor device 1 of FIG. 1A. FIG. 1C is a schematic exploded view of the sensor device 1 of FIGS. 1A and 1B.

The sensor device 1 can comprise a support structure 10 and a cap 12. The sensor device 1 can comprise a vibration sensor device that can monitor vibration of a vibration source (not shown). The vibration source can include a steam pipe or boiler wall in a power plant, a tailpipe or engine of an automobile, etc. The support structure 10 can comprise a base 14 and a carrier 16. The cap 12 can comprise a top cover 18 and a sidewall 20. The sensor device 1 can comprise a sensor module 22. A stud 24 can be coupled to the base 14 of the support structure 10. The stud 24 can be coupled to the vibration source, thereby coupling the support structure 10 and the vibration source. For example, in some embodiments, the stud 24 can comprise threads to threadably connect to a portion of the vibration source. A connector 26 can be coupled to the cap 12. The connector 26 can receive and electrically connect to a connection line to electrically connect the sensor device 1 with an external substrate or system (not shown) for processing data from the sensor module 22. The external substrate or system can comprise a data acquisition board, such as EVAL-CN0540-ARDZ manufactured by Analog Devices, Inc. The support structure 10 and the cap 12 can be coupled by way of fasteners 28 (e.g., screws). The connector 26 and the cap 12 can be coupled by way of fasteners 29 (e.g., screws).

The sensor module 22 can comprise a sensor die (not illustrated) mounted to a substrate 30. In some embodiments, the sensor die can comprise a microelectromechanical systems (MEMs) sensor die. In some embodiments, the substrate 30 can comprise a printed circuit board (PCB). The substrate 30 can be coupled with the carrier 16 by way of fasteners 32 (e.g., screws). In some embodiments, electronics, such as a filter, can be mounted to the substrate 30 for processing data from the sensor die of the sensor module 22. The sensor device 1 can have an integrated electronics piezoelectric (IEPE) interface. In some embodiments, the connector 26 can comprise a subminiature version A (SMA) connector. The sensor module 22 can be configured to be compatible with the SMA connector. Although the illustrated connector 26 comprises an SMA connector, other types of connectors that provide electrical and/or data communication with an external device may be used in the disclosed embodiments.

FIGS. 1D is a schematic top plan view of a sensor device 1′ according to an embodiment. FIG. 1E is a schematic side view of the sensor device 1′. FIG. 1F is another schematic side view of the sensor device 1′. Unless otherwise noted, components of the sensor device 1′ illustrated in FIGS. 1D-1F may be the same as or similar to like components of the sensor device 1 illustrated in FIGS. 1A-1C. The sensor device 1′ is generally similar to the sensor device 1, except that the sensor device 1′ includes screws 31 that can couple a cap 12 to a support structure 10. The screws 31 can extend through portions of a sidewall 20 and into portions of the support structure 10.

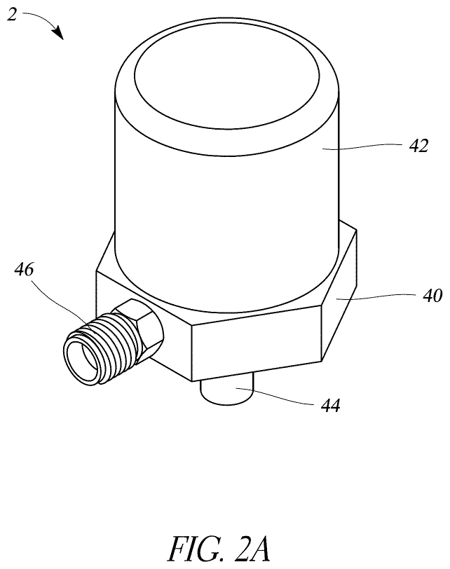

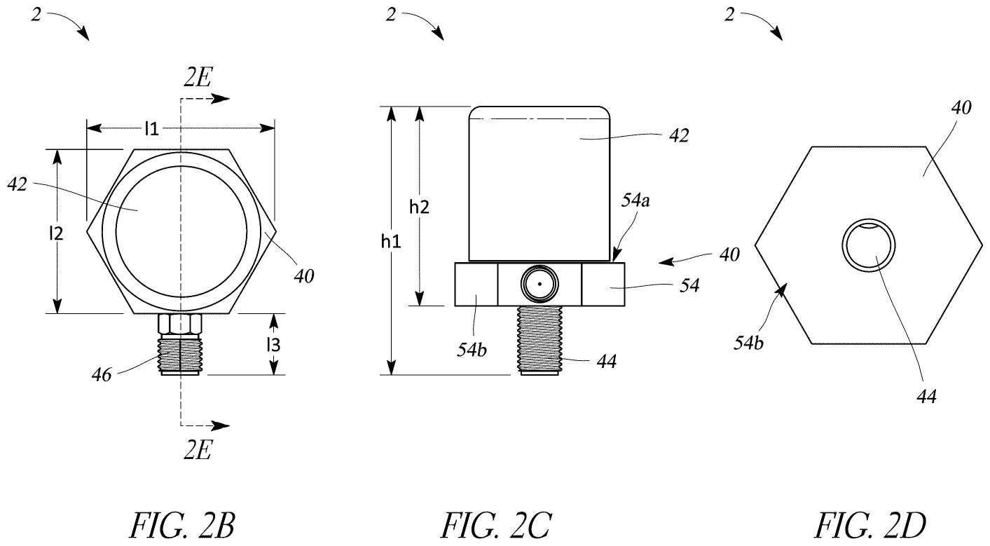

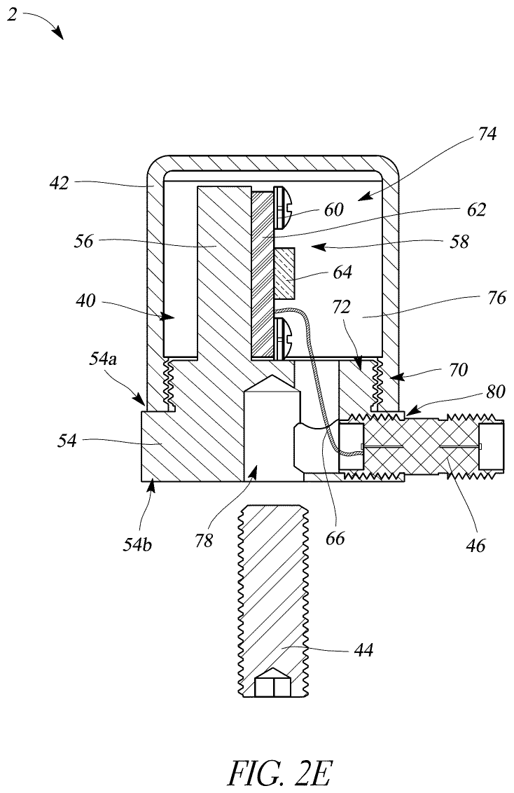

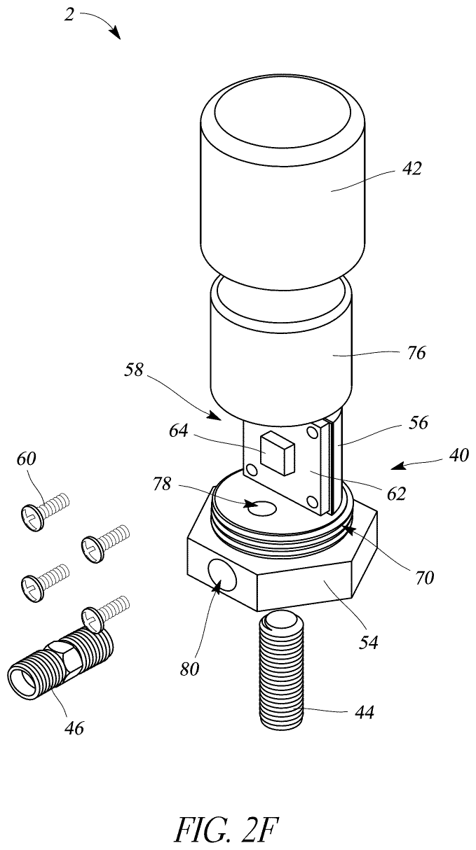

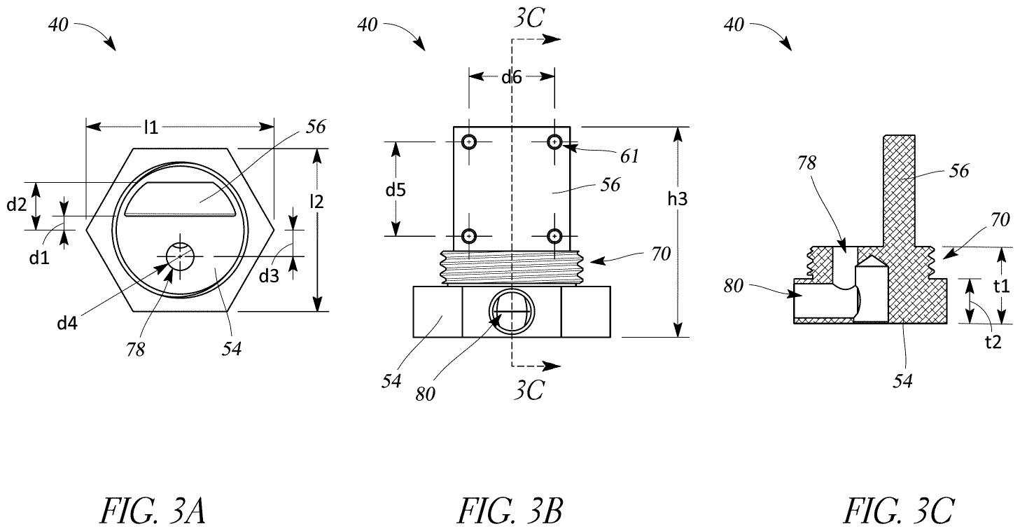

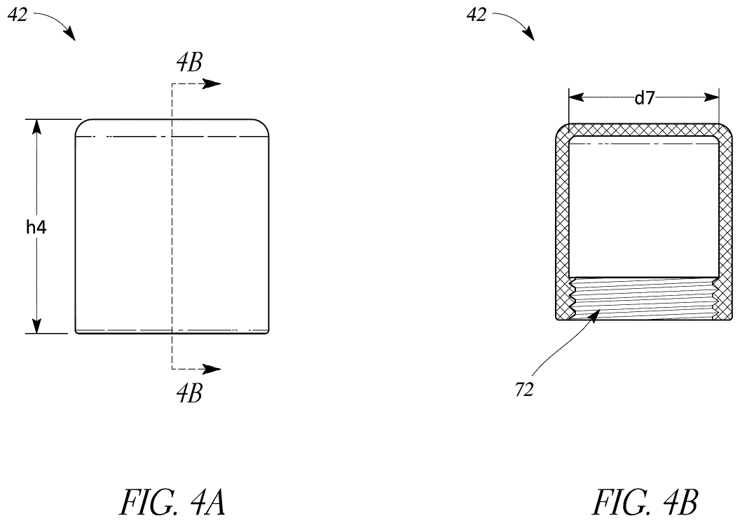

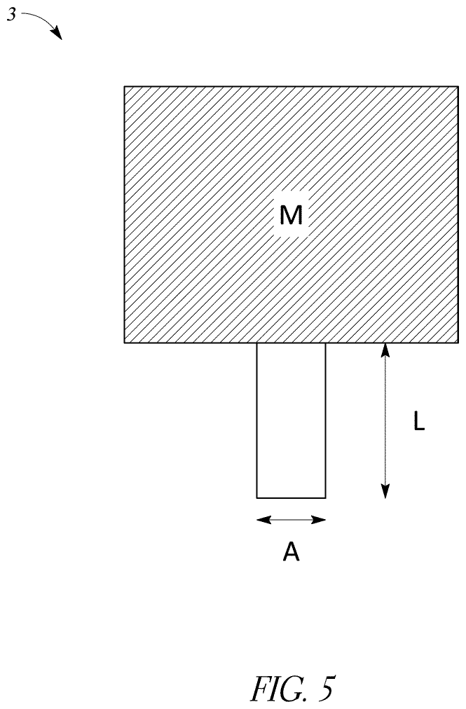

FIGS. 2A-2F illustrate schematic views of a sensor device 2 that includes a support structure 40 and a cap 42, according to an embodiment. FIGS. 3A-3C illustrate schematic views of the support structure 40 of the sensor device 2. FIGS. 4A-4B illustrate schematic views of the cap 42 of the sensor device 2. Unless otherwise noted, components of the sensor device 2 illustrated in FIGS. 2A-4B may be the same as or similar to like components of the sensor device 1 illustrated in FIGS. 1A-1F.

FIG. 2A is a schematic perspective view of the sensor device 2. FIG. 2B is a schematic top plan view of the sensor device 2. FIG. 2C is a schematic side view of the sensor device 2. FIG. 2D is a schematic bottom plan view of the sensor device 2. FIG. 2E is a schematic cross-sectional side view of the sensor device 2. FIG. 2F is an exploded view of the sensor device 2. FIG. 3A is a schematic top plan view of the support structure 40. FIG. 3B is a schematic side view of the support structure 40. FIG. 3C is a schematic cross-sectional side view of the support structure 40. FIG. 4A is a schematic side view of the cap 42. FIG. 4B is a schematic cross-sectional side view of the cap 42.

The sensor device 2 can comprise a vibration sensor device that can monitor vibration of a vibration source (not shown). The vibration source can include a steam pipe or boiler wall in a power plant, a tailpipe or engine of an automobile, etc. The sensor device 2 can be mechanically connected to the vibration source. In some embodiments, the sensor device 2 can be connected with the vibration source by way of a stud 44. The sensor device 2 can include a connector 46 that is coupled with the support structure 40. In some embodiments, the sensor device 2 can have an integrated electronics piezoelectric (IEPE) interface. In some embodiments, the connector 46 can comprise a subminiature connector, such as a subminiature version A (SMA) connector. The connector 46 can receive a connection line to electrically connect the sensor device 2 with an external substrate or system (not shown) for processing data from the sensor device 2. The external substrate or system can comprise a data acquisition board, such as EVAL-CN0540-ARDZ manufactured by Analog Devices, Inc. In some embodiments, a mechanical resonant frequency of the sensor device 2 can be above 5 kHz, above 7 kHz, or at least 10 kHz, e.g., about 10 kHz in some embodiments. For example, the mechanical resonant frequency of the sensor device 2 can be in a range of 5 kHz to 20 kHz, in a range of 7 kHz to 20 kHz, in a range of 10 kHz to 20 kHz, in a range of 5 kHz to 15 kHz, or in a range of 7 kHz to 15 kHz.

The support structure 40 can include a platform or base 54, and a carrier 56 coupled to or integrally formed with the base 54. The base 54 has an upper side 54a and a lower side 54b. The carrier 56 can extend non-parallel (e.g., vertically) from the upper side 54a of the base 54. The sensor device 2 can include a sensor module 58 that is mounted to the carrier 56. The sensor module 58 can comprise a substrate 62 and a sensor die 64 mounted to the substrate 62. In some embodiments, the sensor module 58 can comprise electronics (not shown) mounted on the substrate 62 for pre-processing the signal from the sensor die 64. For example, the sensor module 58 can comprise EVAL-CN0532-EBZ manufactured by Analog Devices, Inc. In some embodiments, the sensor module can be in direct contact with the carrier 56. In some embodiments, the sensor module 58 can be mechanically connected to the carrier 56 by way of a fastener 60, such as a screw. For example, the fastener 60 can extend through a thickness of the substrate 62 and into a hole 61 (e.g., a screw hole 61) to couple the sensor module 58 to the carrier 56. In some embodiments, the fastener can comprise a metal, such as aluminum or stainless steel. In some embodiments, the sensor die 64 can comprise a vibration sensor die. In some embodiments, the sensor die 64 can comprise a microelectromechanical systems (MEMs) sensor die. For example, the sensor die 64 can comprise ADXL1002 manufactured by Analog Devices, Inc. In some embodiments, the sensor die 64 can be configured to detect vibration of about 11 kHz. For example, the sensor die 64 can be configured to detect vibration of about 11 kHz at about 3 dB. For example, the sensor die 64 can be configured to detect vibration in a range of 0.1 Hz to 11 kHz at about 3 dB. The sensor module 58 can be positioned vertically relative to a horizontal plane of the upper side 54a of the base 54. For example, as shown, a longer dimension of the sensor module 58 can be oriented non-parallel relative to (e.g., approximately perpendicular to) the base 54. The sensor module 58 can be configured to sense vertical vibration propagated from the sensor source through the stud 44.

The sensor module 58 and the connector 46 can be electrically connected by way of a conductive wire 66. The conductive wire 66 can comprise a signal line. In some embodiments, the support structure 40 can comprise a conductive material and provide a ground connection for the sensor module 58. In some embodiments, the sensor module 58 can receive the ground connection at least through the screws 60 and the support structure 40. In some embodiments, the sensor module 58 and the connector 46 can be signally connected by a single conductive wire.

The support structure 40 can comprise any suitable conductive or non-conductive material. In some embodiments, the support structure 40 can comprise a metal. In some embodiments, the support structure 40 can comprise a material that has relatively high Young's modulus, such as at least 60 GPa. For example, the support structure 40 can comprise a material that has Young's modulus in a range of 60 GPa to 200 GPa, in a range of 60 GPa to 100 GPa, or in a range of 65 GPa to 100 GPa. In some embodiments, the support structure 40 can comprise a material that has a relatively low density, such as less than 4000 kg/m³. For example, the support structure 40 can comprise a material that has a density in a range of 2000 kg/m³ to 4000 kg/m³, in a range of 2000 kg/m³ to 3000 kg/m³, in a range of 2500 kg/m³ to 4000 kg/m³, or in a range of 2500 kg/m³ to 3000 kg/m³. In some embodiments, the support structure 40 can comprise a material that has a density less than 8500 kg/m³. For example, the support structure 40 can comprise a material that has a density in a range of 4000 kg/m³ to 8500 kg/m³, in a range of 5000 kg/m³ to 8500 kg/m³, in a range of 5000 kg/m³ to 8000 kg/m³, or in a range of 6000 kg/m³ to 8000 kg/m³. In some embodiments, the support structure 40 can comprise aluminum (e.g., 6061-T6 aluminum). In other embodiments, the support structure 40 can comprise stainless steel.

The upper side 54a of the base 54 can include a threaded portion 70. The cap 42 can comprise a screw top design that include a threaded portion 72. The threaded portion 70 of the base 54 can mate with a corresponding threaded portion 72 of the cap 42 to mechanically couple one another. The base 54 of the support structure 40 and the cap 42 can together define a cavity 74. The carrier 56 and the sensor module 58 can be positioned in the cavity 74. In some embodiments, a filler material 76 can be disposed in the cavity 74. The filler material 76 can comprise a non-conductive material, such as a non-conductive epoxy. In some embodiments, the filler material 76 can be injected into the cavity 74 in a liquid state and be solidified over time at room temperature. In some embodiments, the filler material 76 can be injected into the cavity 74 through an opening 78 in the base 54 of the support structure 40. In some embodiments, the filler material 76 can comprise a low viscosity material. For example, the filler material 76 can comprise CA40 manufactured by 3M Company. In some embodiments, the filler material 76 can increase the resonant frequency of the sensor device 2. However, in some embodiments, the filler material 76 can propagate non-targeted vibration to the sensor module. Therefore, the filler material 76 can be omitted depending on a desired specification of the final product.

The opening 78 in the base 54 can be used for injecting the filler material 76 as described above and/or for receiving the stud 44. In some embodiments, at least a portion of the stud 44 can extend into the opening 78 from the lower side 54b and another portion of the stud 44 can be coupled to a vibration source thereby mechanically connecting the sensor module 58 and the vibration source through at least the support structure 40 and the stud 44. In some embodiments, the stud 44 can comprise a male thread and the opening 78 can comprise a female thread for receiving the make thread of the stud 44. In some embodiments, the stud 44 can comprise the same, a similar, or a different material as the support structure 40. In some embodiments, the stud 44 can comprise stainless steel. In some embodiments, the base 54 can comprise a hex-shape. In such embodiments, the sensor device 2 can be connected to the vibration source relatively easily using a tool such as a hex-wrench.

The sensor device 2 can comprise a connection port 80 for receiving the connector 46. In some embodiments, the base 54 of the support structure 40 can comprise the connection port 80. In some embodiments, the connector 46 can comprise a metal such as copper, or an alloy such as brass.

The cap 42 can comprise any suitable conductive or non-conductive material. In some embodiments, the cap 42 can comprise a metal. In some embodiments, the cap 42 can comprise a material that has relatively high Young's modulus, such as at least 60 GPa. For example, the cap 42 can comprise a material that has Young's modulus in a range of 60 GPa to 200 GPa, in a range of 60 GPa to 100 GPa, or in a range of 65 GPa to 100 GPa. In some embodiments, the cap 42 can comprise a material that has a relatively low density, such as less than 4000 kg/m³. For example, the cap 42 can comprise a material that has a density in a range of 2000 kg/m³ to 4000 kg/m³, in a range of 2000 kg/m³ to 3000 kg/m³, in a range of 2500 kg/m³ to 4000 kg/m³, or in a range of 2500 kg/m³ to 3000 kg/m³. In some embodiments, the cap 42 can comprise a material that has a density less than 8500 kg/m³. For example, the cap 42 can comprise a material that has a density in a range of 4000 kg/m³ to 8500 kg/m³, in a range of 5000 kg/m³ to 8500 kg/m³, in a range of 5000 kg/m³ to 8000 kg/m³, or in a range of 6000 kg/m³ to 8000 kg/m³ . In some embodiments, the cap 42 can comprise aluminum (e.g., 6061-T6 aluminum). In other embodiments, the cap 42 can comprise another metal, such as stainless steel.

The sensor device 2 has a height h1 with the stud 44 and a height h2 without the stud 44. In some embodiments, the height h1 of the sensor device 2 with the stud 44 can be about 43.5 mm. For example, the height h1 can be in a range of 30 mm to 60 mm, in a range of 35 mm to 60 mm, in a range of 40 mm to 60 mm, in a range of 30 mm to 50 mm, in a range of 30 mm to 45 mm, in a range of 35 mm to 50 mm, in a range of 40 mm to 45 mm. In some embodiments, the height h2 of the sensor device 2 without the stud 44 can be about 32.5 mm. For example, the height h2 can be in a range of 30 mm to 40 mm, in a range of 32 mm to 40 mm, in a range of 30 mm to 37 mm, or in a range of 32 mm to 37 mm. In some embodiments, prodtuded height of the stud 44 (h1-h2) can be in a range of 8 mm to 12 mm, 10 mm to 12 mm, or 10 mm to 11 mm.

The hex-shaped base 54 has a length l1 across diagonally opposing corners and a length l2 across diagonally opposing sides. The connector 46 can extend out from the base 54 by a length l3. In some embodiments, the length l1 can be about 27.7 mm. For example, the length l1 can be in a range from 20 mm to 40 mm, in a range from 25 mm to 40 mm, in a range from 20 mm to 35 mm, in a range from 20 mm to 30 mm, in a range from 25 mm to 35 mm, or in a range from 25 mm to 30 mm. In some embodiments, the length l2 can be about 24 mm. For example, the length l2 can be in a range from 15 mm to 35 mm, in a range from 20 mm to 35 mm, in a range from 15 mm to 30 mm, or in a range from 20 mm to 30 mm. In some embodiments, the length l3 can be about 9 mm. For example, the length l3 can be in a range from 5 mm to 15 mm, in a range from 7 mm to 15 mm, in a range from 5 mm to 10 mm, or in a range from 7 mm to 10 mm.

The carrier 56 can be laterally or horizontally offset from the center of the base 54 on the upper side 54a. In some embodiments, the carrier 56 can be positioned between a distance d1 and a distance d2 from the center of the upper side 54a of the base 54. In some embodiments, the distance d1 can be about 2 mm and the distance d2 can be about 7 mm. For example, the distance d1 can be in a range from 0.5 mm to 5 mm, in a range from 1 mm to 5 mm, in a range from 0.5 mm to 3 mm, or in a range from 1 mm to 3 mm. For example, the distance d1 can be in a range from 4 mm to 10 mm, in a range from 5 mm to 10 mm, in a range from 4 mm to 8 mm, or in a range from 5 mm to 8 mm.

The opening 78 at the lower side 54b can be positioned at or near the center of the base 54. The opening 78 at the upper side 54a can be laterally or horizontally offset from the center of the base 54 by a distance d3. In some embodiments, the distance d3 can be about 4 mm such that a center of the opening 78 is offset about 4 mm laterally from the center of the base 54. For example, the distance d3 can be in a range of 0.5 mm to 10 mm, in a range of 2 mm to 10 mm, in a range of 0.5 mm to 7 mm, or in a range of 2 mm to 7 mm.

The opening 78 has a diameter d4 at the upper side 54a of the base 54. In some embodiments, the diameter d4 of the opening can be about 4 mm. For example, the diameter d4 can be in a range of 1 mm to 10 mm, in a range of 2 mm to 10 mm, in a range of 1 mm to 7 mm, or in a range of 2 mm to 7 mm.

In some embodiments, the holes 61 that receive the fasteners 60 can be positioned at or near four corners of the carrier 56 (see FIG. 3B). The holes 61 positioned at or near upper corners of the carrier 56 can be vertically spaced from the holes 61 positioned at or near lower corners of the carrier 56 by a distance d5. The holes 61 positioned at or near the upper corners of the carrier 56 can be horizontally spaced from each other by a distance d6. In some embodiments, the distance d5 can be about 13.21 mm. For example, the distance d5 can be in a range from 5 mm to 20 mm, in a range from 10 mm to 20 mm, in a range from 5 mm to 15 mm, or in a range from 10 mm to 15 mm. In some embodiments, the distance d6 can be about 12.7 mm. For example, the distance d6 can be in a range from 5 mm to 20 mm, in a range from 10 mm to 20 mm, in a range from 5 mm to 15 mm, or in a range from 10 mm to 15 mm.

The base 54 has a thickness t1 without the threaded portion 70 and a thickness t2 with the threaded portion 70. In some embodiments, the thickness t1 can be about 12 mm and the thickness t2 can be about 7 mm. For example, the thickness t1 can be in a range of 5 mm to 25 mm, in a range of 10 mm to 25 mm, in a range of 5 mm to 15 mm, or in a range of 10 mm to 15 mm. For example, the thickness t2 can be in a range of 5 mm to 20 mm, in a range of 5 mm to 15 mm, or in a range of 10 mm to 15 mm.

The cap 42 has a height h4 and a diameter d7. In some embodiments, the height h4 of the cap 42 can be about 25.5 mm, and the diameter d7 can be about 20 mm. For example, the height h4 can be in a range from 15 mm to 50 mm, in a range from 20 mm to 50 mm, in a range from 15 mm to 40 mm, in a range from 15 mm to 30 mm, in a range from 20 mm to 40 mm, or in a range from 20 mm to 30 mm. For example the diameter d7 can be in a range of 10 mm to 45 mm, in a range of 15 mm to 30 mm, in a range of 10 mm to 25 mm, in a range of 15 mm to 30 mm, or in a range of 15 mm to 25 mm.

A total weight of a sensor device disclosed herein can be about 91.5 g, in some embodiments. A total weight of a sensor device disclosed herein can be about 33.69 g, in some embodiments. For example, the total weight of a sensor device disclosed herein can be in a range of 25 g to 100 g, in a range of 25 g to 40 g, in a range of 30 g to 40 g, in a range of 25 g to 35 g, in a range of 30 g to 35 g, in a range of 85 g to 100 g, in a range of 90 g to 100 g, in a range of 85 g to 95 g, or in a range of 90 g to 95 g

The materials of the support structure 40, the cap 42, and the filler material 76, and/or the dimensions of various portions of the sensor device 2 can be selected to enable the mechanical resonant frequency of the sensor device 2 to be above 5 kHz, above 7 kHz, or at least 10 kHz, e.g., about 10 kHz in some embodiments. For example, the mechanical resonant frequency of the sensor device 2 can be in a range of 5 kHz to 20 kHz, in a range of 7 kHz to 20 kHz, in a range of 10 kHz to 20 kHz, in a range of 5 kHz to 15 kHz, or in a range of 7 kHz to 15 kHz.

FIG. 5 shows a schematic diagram of a sensor device 3. A mechanical resonant frequency f can be calculated using the equation (Equations 1 and 2) shown below.

$$f = \frac{1}{2 π} \sqrt{\frac{E \cdot L}{A \cdot M}} ; \qquad ( Equation 1 )$$

$$E = \frac{F \cdot L}{A \cdot Δ L} = Young ' s Modulus \qquad ( Equation 2 )$$

E represents the Young's modulus (modulus of elasticity); F represents a force exerted on an object under tension; A represents an actual cross-sectional area, which equals the area of the cross-section perpendicular to the applied force; L represents a length of between a vibration source and a sensor module of the sensor device; αL represents a difference in length L caused by vibration from the vibration source; and M represents a mass. Various embodiments disclosed herein can enable the sensor device s to have the resonant frequency to be in a range of 5 kHz to 20 kHz, in a range of 7 kHz to 20 kHz, in a range of 10 kHz to 20 kHz, in a range of 5 kHz to 15 kHz, or in a range of 7 kHz to 15 kHz.

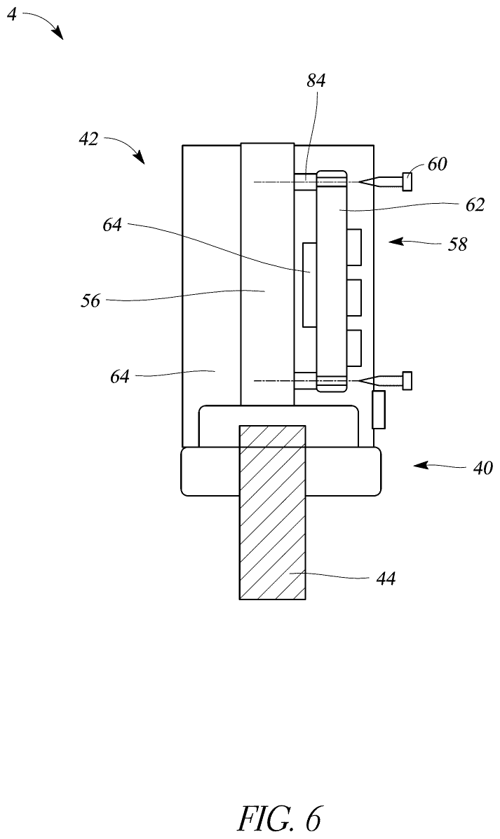

FIG. 6 is a schematic cross sectional side view of a sensor device 4. Unless otherwise noted, components of the sensor device 4 illustrated in FIGS. 1D-1F may be the same as or similar to like components of the sensor devices disclosed herein. The sensor device 4 is generally similar to the sensor device 2. However, unlike the sensor deice 2, in the sensor device 4, a sensor die 64 can be positioned between a substrate 62 and a carrier 56. The sensor device 4 can include a spacer 84 between the substrate 62 and the carrier 56. The spacer 84 can provide enough spacing for the sensor die 64. A fastener 60, such as a screw, can couple the sensor module 58 and the carrier 56.

As compared to the sensor device 4 illustrated in FIG. 6, certain embodiments of the sensor device 2 illustrated in FIG. 2E, in which the substrate 62 is attached to the carrier 56 without the spacer 84, can make the sensor device 2 more rigid and transfer less vibration to the sensor module 58. In some embodiments, the sensor device 2 can reduce sensor noise at the sensor module 58 as compared to the sensor device 4. For example, the sensor noise can be less than 25 ug/√Hz in some embodiments.

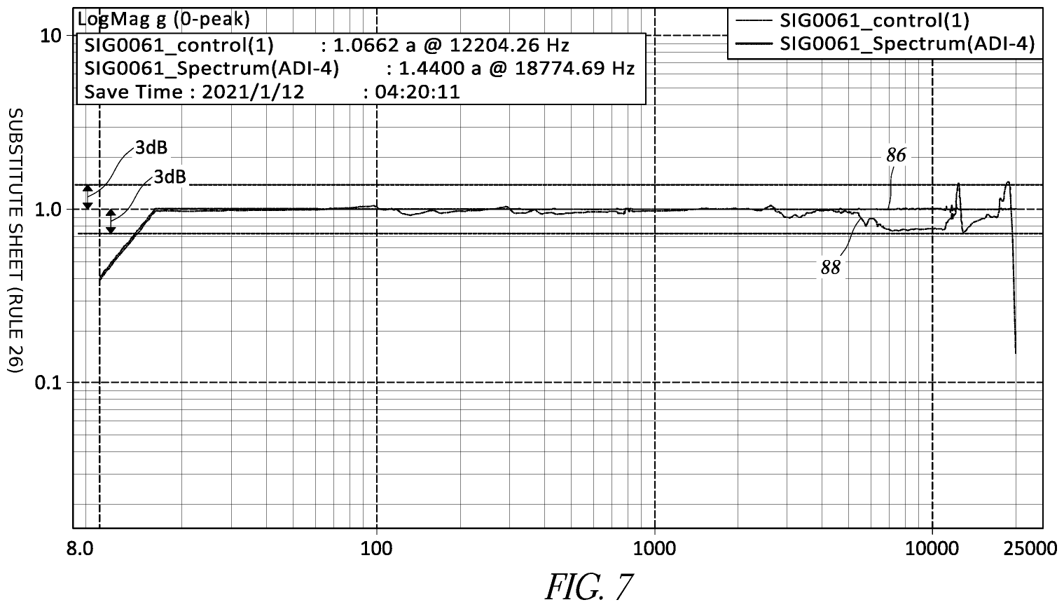

FIG. 7 is a graph showing resonant frequency response curves 86, 88 of two different sensor devices. The curve 86 illustrates the frequency response of a piezoelectric sensor device and the curve 88 illustrates the frequency response of a MEMS sensor device that utilizes a housing disclosed herein. As shown in FIG. 7, the MEMS sensor performs as well as the piezoelectric sensor under 20 kHz. In other words, the curve 88 can be within a range of frequency response variation relative to the curve 86 below 20 kHz. For example, the curve 88 can be within +/−3 dB of the curve 86 below 20 kHz.

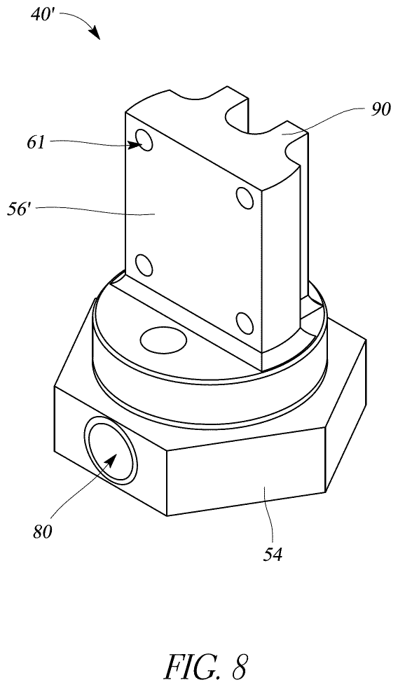

FIG. 8 is a schematic perspective view of a support structure 40′ according to an embodiment. The support structure 40′ can be implemented in any sensor devices disclosed herein. The support structure 40′ can be generally similar to the support structure 40 disclosed herein, except that the support structure 40′ includes a back support 90 on a side of a carrier 56′. The back support 90 can change the mass of the support structure 40′ and/or the center of mass of a sensor device thereby contributing to optimizing the mechanical resonant frequency of the sensor device. The back support 90 can provide stiffness to the support structure 40′ thereby contributing to optimizing the mechanical resonant frequency of the sensor device. In some embodiments, the back support 90 can be a portion of the carrier 56′. The support structure 40′ can be used in place of the support structure 40 in a sensor device.

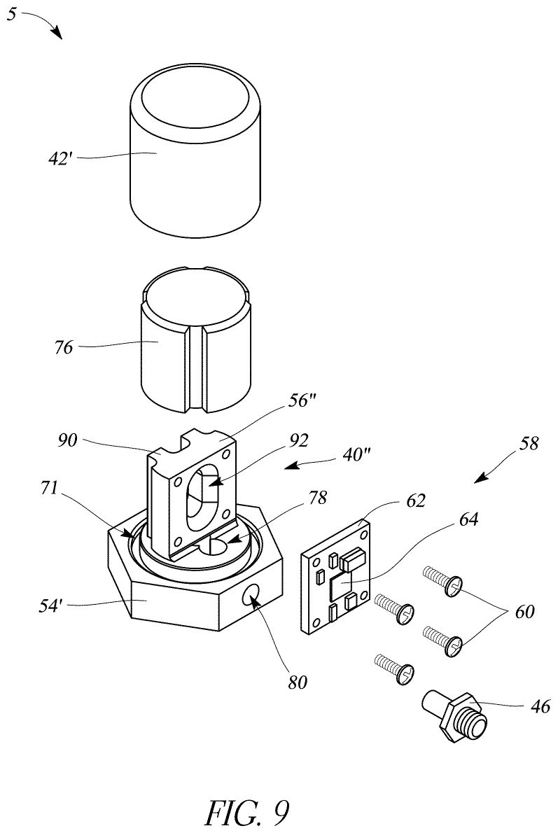

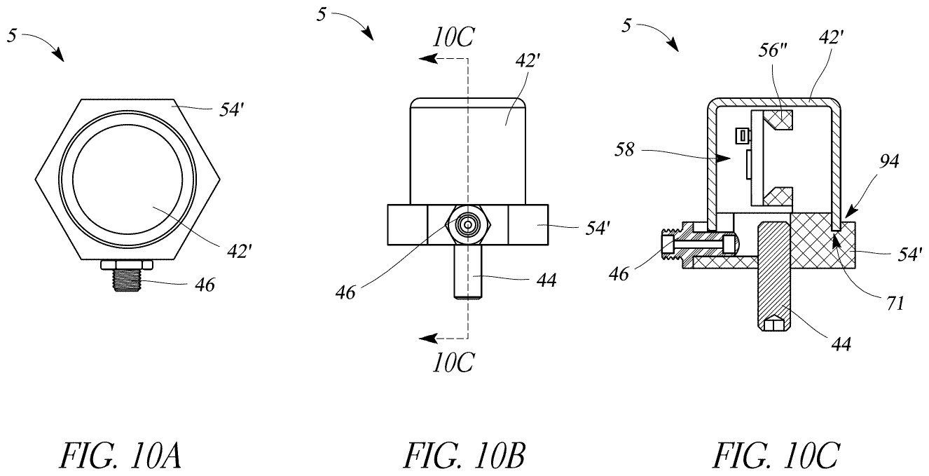

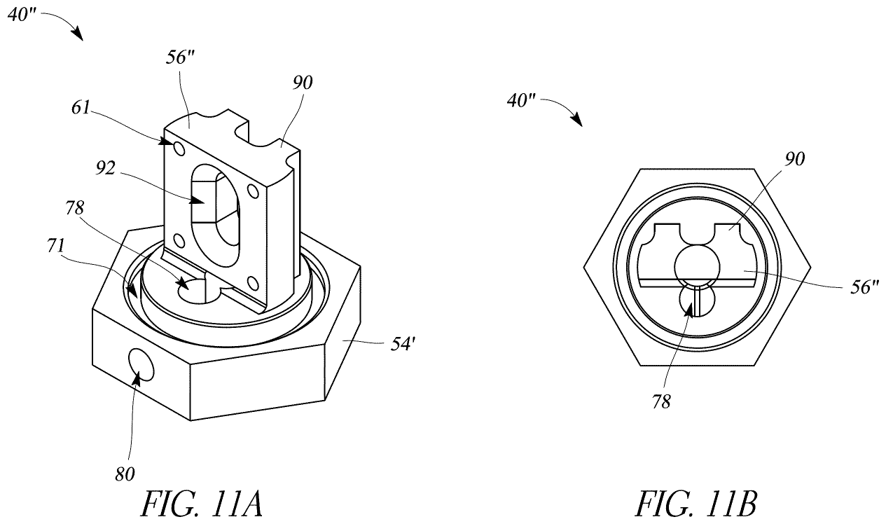

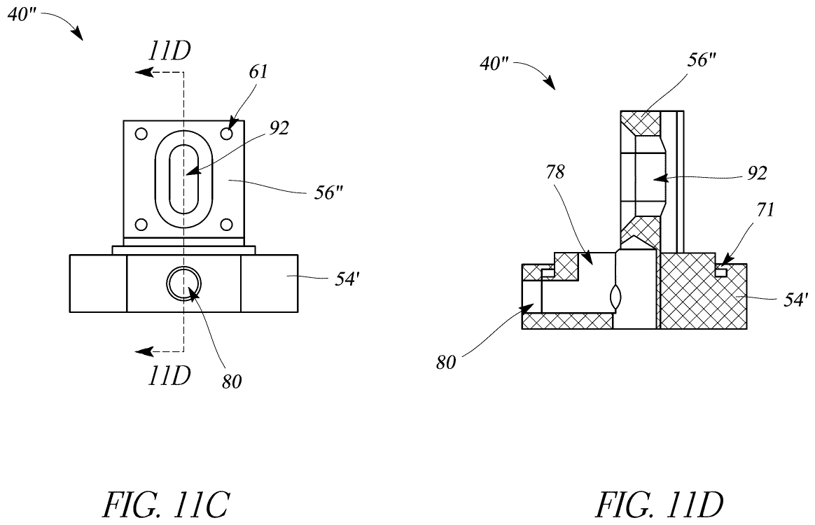

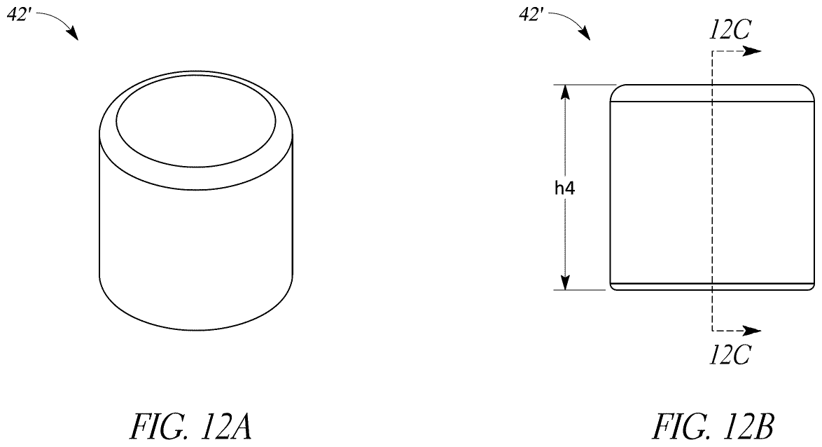

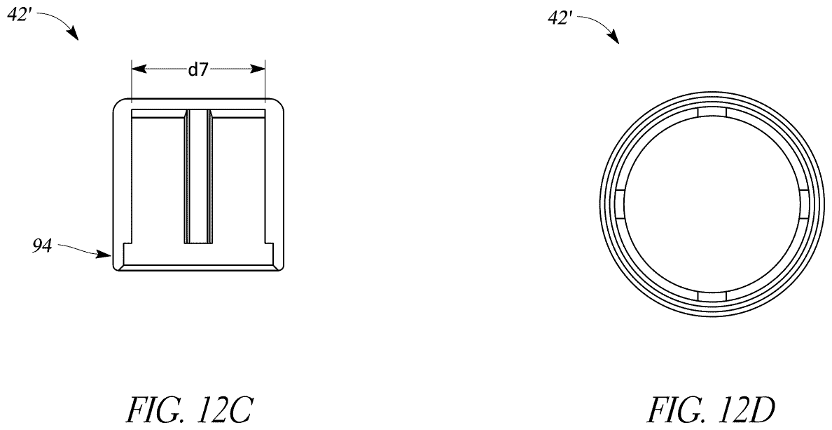

FIGS. 9-10C illustrate schematic views of a sensor device 5 that includes a support structure 40″ and a cap 42′, according to an embodiment. FIGS. 11A-11D illustrate schematic views of the support structure 40″ of the sensor device 5. FIGS. 12A-12D illustrate schematic views of the cap 42′ of the sensor device 5. Unless otherwise noted, components illustrated in FIGS. 9-12D may be the same as or similar to like components of the components illustrated in FIGS. 1A-6, and 8.

FIG. 9 is an exploded view of the sensor device 5. FIG. 10A is a schematic top plan view of the sensor device 5. FIG. 10B is a schematic side view of the sensor device 5. FIG. 10C is a schematic cross-sectional side view of the sensor device 2. FIG. 11A is a schematic perspective view of the support structure 40″. FIG. 11B is a schematic top plan view of the support structure 40″. FIG. 11C is a schematic side view of the support structure 40″. FIG. 11D is a schematic cross-sectional side view of the support structure 40″. FIG. 12A is a schematic perspective view of the cap 42′. FIG. 12B is a schematic side view of the cap 42′. FIG. 12C is a schematic cross-sectional side view of the cap 42′. FIG. 12D is a schematic top plan view of the cap 42′.

The sensor device 5 can be generally similar to the sensor device 2 except that the cap 42′ of the sensor device 5 is press fit connected to the support structure 40″, and the support structure 40″ of the sensor device 5 comprises a carrier 56′ that includes an back support 90 and an opening 92.

The cap can 42′ can comprise a male contact portion 94 and the support structure 40″ can comprise a female contact portion 71. In some embodiments, the male contact portion 94 can be a thinned portion at an end of the cap 42′, and the female contact portion can comprise a annular trench, cavity, or groove formed on an upper surface of the base 54′ of the support structure 40″. In some embodiments, the male contact portion 94 can be disposed in the female contact portion 71, and a force can be applied to deform the male contact portion 94 of the cap 42′ thereby coupling the cap 42′ to the base 54′. In certain applications, the cap 42′ that is press fit connected to the support structure 40″ can reduce vibrations caused at a gap between the threaded portion 70 and the threaded portion 72 that is present in the sensor device 2. The female contact portion can contribute to minimizing the total height and overall weight of the sensor device 5.

In some embodiments, the opening 92 formed in the carrier 56′ of the support structure 40″ can comprise a through hole formed through a thickness of the carrier 56′. In the illustrated embodiment, the opening 92 comprises only one oval hole. However, the opening 92 can comprise a plurality of holes, in some other embodiments. The opening 92 can reduce the weight of the carrier 56′ thereby enabling the overall weight of the sensor device 5 to be reduced.

The materials of the support structure 40′ and the cap 42′ and/or the dimensions of various portions of the sensor device 5 can be selected to enable the mechanical resonant frequency of the sensor device 5 to be above 5 kHz, above 7 kHz, or at least 10 kHz, e.g., about 10 kHz in some embodiments. For example, the mechanical resonant frequency of the sensor device 5 can be in a range of 5 kHz to 20 kHz, in a range of 7 kHz to 20 kHz, in a range of 10 kHz to 20 kHz, in a range of 5 kHz to 15 kHz, or in a range of 7 kHz to 15 kHz.

Any suitable combination(s) of the principles and advantages disclosed herein can be made. The teachings herein are applicable to a variety of systems. Although this disclosure includes some example embodiments, the teachings described herein can be applied to a variety of structures.

Throughout the description and the claims or example embodiments, the words “comprise,” “comprising,” “include,” “including,” and the like are to generally be construed in an inclusive sense, as opposed to an exclusive or exhaustive sense; that is to say, in the sense of “including, but not limited to.” The word “coupled,” as generally used herein, refers to two or more elements that may be either directly coupled to each other, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural may also include the plural or singular, respectively. The word “or” in reference to a list of two or more items, is generally intended to encompass all of the following interpretations of the word: any of the items in the list, all of the items in the list, and any combination of the items in the list. The x-axis, y-axis, and z-axis used herein may be defined in local coordinates in each element or figure, and may not necessarily correspond to fixed Cartesian coordinates.

Moreover, conditional language used herein, such as, among others, “can,” “could,” “might,” “may,” “e.g.,” “for example,” “such as” and the like, unless specifically stated otherwise or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding whether these features, elements and/or states are included or are to be performed in any particular embodiment.

While certain embodiments of the inventions have been described, these embodiments have been presented by way of example only, and are not intended to limit the scope of the disclosure. Indeed, the novel methods, apparatus, and systems described herein may be embodied in a variety of other forms; furthermore, various omissions, substitutions and changes in the form of the methods, apparatus, and systems described herein may be made without departing from the spirit of the disclosure. For example, circuit blocks and/or circuit elements described herein may be deleted, moved, added, subdivided, combined, and/or modified. Each of these circuit blocks and/or circuit elements may be implemented in a variety of different ways. The accompanying claims and their equivalents are intended to cover any such forms or modifications as would fall within the scope and spirit of the disclosure.

1.-64. (canceled)

65. A sensor package comprising:
a support structure configured to couple with a vibration source by way of a stud;
a cap at least partially disposed over the support structure, the cap at least partially defining a cavity; and
a vibration sensor module coupled to a portion of the support structure and disposed in the cavity,
wherein the sensor package has a mechanical resonant frequency in a range of 0.1 Hz to 11 kHz.

66. The sensor package of claim 65, wherein the support structure includes a base and a carrier, the base having an upper side and a lower side, the carrier disposed on the upper side of the base, the base configured to couple with the vibration source by way of the stud, the cap at least partially disposed over the upper side of the base, the carrier disposed in the cavity, and the vibration sensor module coupled to the carrier.

67. The sensor package of claim 66, wherein the cap comprises a screw top, the upper side of the base comprises a threaded portion, and the screw top mates with the threaded portion to mechanically connect the cap and the base.

68. The sensor package of claim 66, wherein the vibration sensor module comprises a sensor die mounted to a substrate, and the substrate is positioned between the carrier and the sensor die.

69. The sensor package of claim 70, wherein the sensor die comprises a microelectromechanical systems (MEMs) sensor die.

70. The sensor package of claim 66, wherein the stud is configured to couple to the lower side of the base and extends vertically relative to the lower side of the base.

71. The sensor package of claim 66, wherein the carrier extends vertically from the upper side of the base, and the vibration sensor module configured to sense vibration in a vertical direction.

72. The sensor package of claim 65, wherein the support structure comprises a material that has a Young's modulus in a range of 60 GPa to 200 GPa.

73. The sensor package of claim 72, wherein the material has a density in a range of 2000 kg/m³ to 3000 kg/m³.

74. The sensor package of claim 73, wherein the material comprises aluminum.

75. The sensor package of claim 65, further comprising a filler material disposed in the cavity.

76. The sensor package of claim 75, wherein the filler material comprises a non-conductive epoxy.

77. The sensor package of claim 76, wherein the support structure includes an injection hole for injecting the filler material.

78. The sensor package of claim 65, wherein the sensor package has a mechanical resonant frequency in a range of 5 kHz to 11 kHz.

79. A sensor package comprising:
a support structure configured to couple with a vibration source by way of a stud;
a cap at least partially disposed over the support structure, the cap at least partially defining a cavity;
a microelectromechanical systems (MEMs) vibration sensor module coupled to the support structure and disposed in the cavity; and
a connector coupled to the support structure, the connector configured to connect to a connection line to electrically connect the vibration sensor module to an external substrate or system.

80. The sensor package of claim 79, wherein the connector has an integrated electronics piezoelectric (IEPE) interface.

81. The sensor package of claim 79, wherein the support structure includes a base and a carrier, the base having an upper side and a lower side, the carrier disposed on the upper side of the base, the base configured to couple with the vibration source by way of the stud, the carrier disposed in the cavity, the MEMs vibration sensor module coupled to the carrier, and the connector coupled to the base.

82. A sensor package comprising:
a support structure including a base and a carrier, the base having an upper side and a lower side, the carrier disposed on the upper side of the base, the base configured couple with a vibration source by way of a stud;
a cap at least partially disposed over the upper side of the base, the carrier disposed in a cavity formed at least in part by the base and the cap; and
a microelectromechanical systems (MEMs) vibration sensor module coupled to the carrier and disposed in the cavity;
wherein the support structure comprises a material that has a Young's modulus of at least 60 GPa and a density less than 3000 kg/m³.

83. The sensor package of claim 82 having an integrated electronics piezoelectric (IEPE) interface that includes a subminiature version A (SMA) connector coupled to the base and configured to electrically connect the MEMs vibration sensor module to an external substrate or system.

84. The sensor package of claim 83, wherein the vibration MEMs sensor module comprises a signal output terminal that is connected with the SMA connector by way of a signal line.
